(19) United States
(12) Patent Application Publication
(10) Pub. No.: US 2007/0272391 A1
(43) Pub. Date: Nov. 29, 2007

(54) HEAT DISSIPATION DEVICE

(75) Inventors: Wan-Lin Xia, Shenzhen (CN); Tao Li, Shenzhen (CN); Jun Long, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Tu-Cheng,Taipei Hsien (TW)

(21) Appl. No.: 11/308,917

(22) Filed: May 25, 2006

(51) Int. Cl. H05K 7/20; H01L 23/34

(52) U.S. Cl. 165/80.3; 165/80.4; 165/104.33; 257/720; 361/700

(57) ABSTRACT

A heat dissipation device includes a first heat transferring body and a second heat transferring body extending from the first heat transferring body with a plurality of second fins mounted thereon. The first heat transferring body has a surface in thermal contact with a component to be cooled and a plurality of first fins mounted thereon. The second heat transferring body with the second fins can dissipate heat originating at the component to be cooled to a place further away from the component to be cooled than the first heat transferring body with the first fins.

### FIELD OF THE INVENTION

The present invention relates to a heat dissipation device, more particularly to a heat dissipation device with a better heat dissipating capability.

### DESCRIPTION OF RELATED ART

As computer technology continues to advance, electronic components such as the central processing units (CPUs) of computers are being made to provide faster operational speeds and greater functional capabilities. When a CPU operates at high speed in a computer enclosure, its temperature usually increases enormously. It is therefore desirable to dissipate the generated heat of the CPU quickly before damage is caused.

A conventional heat dissipation device 20 is illustrated in FIG. 13. The conventional heat dissipation device 20 comprises a heat-conducting block 22 for contacting with a component 30 to be cooled, and a plurality of fins 24 radially and outwardly extending from the heat-conducting block 22. Heat originating at the component 30 is first absorbed by the heat-conducting block 22, and then is conducted to the fins 24 to be dissipated to ambient air. However, the heat-conducting block 22 has a symmetrical cylindrical outer configuration, the heat can only be dissipated to the air surrounding the component 30 via fins 24. Thus, the air surrounding the component 30 is heated up to a high temperature. This adversely affects the heat exchange efficiency between the air and the conventional heat dissipation device 20.

What is needed, therefore, is a heat dissipation device, which can overcome the above-described disadvantages of the prior art.

### SUMMARY OF INVENTION

A heat dissipation device comprises a first heat transferring body and a second heat transferring body extending from the first heat transferring body with a plurality of second fins mounted thereon. The first heat transferring body has a surface in thermal contact with a component to be cooled and a plurality of first fins mounted thereon. The second heat transferring body with the second fins can dissipate heat originating from the component to be cooled to a place further away from the component to be cooled than the first heat transferring body with the first fins.

Other advantages and novel features will become more apparent from the following detailed description of preferred embodiments when taken in conjunction with the accompanying drawings, in which:

### BRIEF DESCRIPTION OF DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a perspective view of a heat dissipation device in accordance with a first preferred embodiment;

FIG. 2 is a diagrammatic view of a heat dissipation device in accordance with a second preferred embodiment;

FIG. 3 is a top plan view of a heat dissipation device in accordance with a third preferred embodiment;

FIG. 4 is a top plan view of a heat dissipation device in accordance with a fourth preferred embodiment;

FIG. 5 is a top plan view of a heat dissipation device in accordance with a fifth preferred embodiment;

FIG. 6 is a perspective view of a heat dissipation device in accordance with a sixth preferred embodiment;

FIG. 7 is an exploded view of the heat dissipation device of FIG. 6;

FIG. 8 is a bottom plan view of the heat dissipation device of FIG. 6;

FIG. 9 is a top plan view of a heat dissipation device in accordance with a seventh preferred embodiment;

FIG. 10 is a top plan view of a heat dissipation device in accordance with an eighth preferred embodiment;

FIG. 11 is a top plan view of a heat dissipation device in accordance with a ninth preferred embodiment;

FIG. 12 is a perspective view of a heat dissipation device in accordance with a tenth preferred embodiment; and

FIG. 13 is a perspective view of a conventional heat dissipation device.

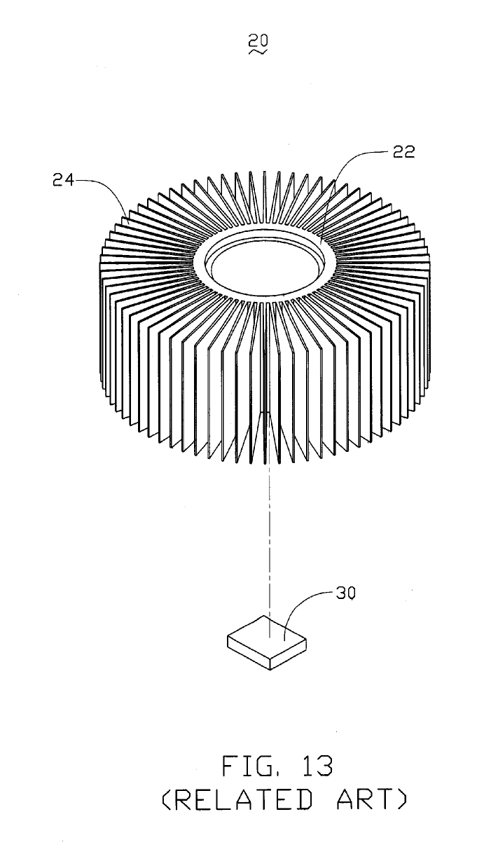

### DETAILED DESCRIPTION

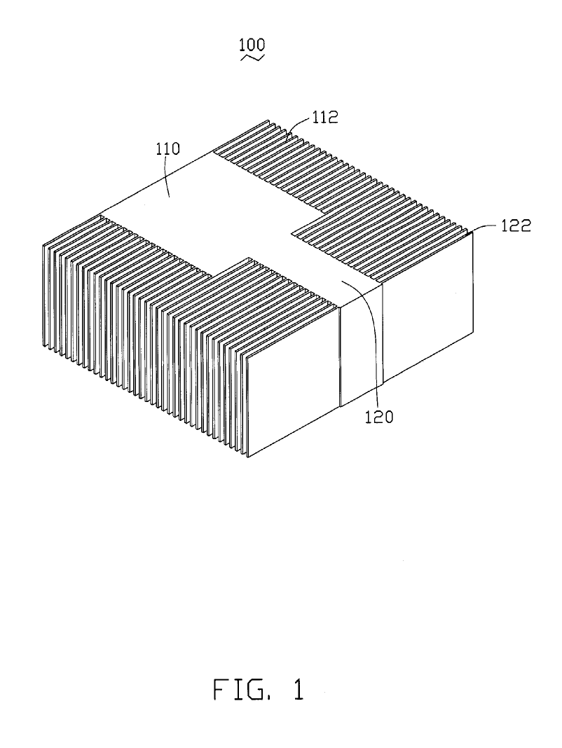

Referring to FIG. 1, a heat dissipation device 100 in accordance with a first preferred embodiment is illustrated. The heat dissipation device 100 comprises a first heat transferring body 110 and a second heat transferring body 120 extending form one side of the first heat transferring body 110 to a place appropriate for heat dissipation, which has a lower temperature or a larger space to increase the heat dissipating efficiency of the heat dissipation device 100. The first and second heat transferring bodies 110, 120 are integrally formed from the same metallic material, and the second heat transferring body 120 has a cross section smaller than that of the first heat transferring body 110.

The first heat transferring body 110 is an elongated cube with a bottom surface (not shown), usually a center portion thereof in thermal contact with a component to be cooled so as to absorb heat therefrom. There is a plurality of first fins 112 perpendicularly extending from opposite sides of the first heat transferring body 110 to dissipate the heat accumulated at the first heat transferring body 110 to the ambient air close to and surrounding the component to be cooled.

The second heat transferring body 120 is a metal block projected from the first heat transferring body 110 along a lengthwise direction of the first heat transferring body 110, and comprises a plurality of second fins 122 perpendicularly extending therefrom. The second heat transferring body 120 serves as a secondary heat conducting component, and is used to transfer part of the heat accumulated at the first heat transferring body 110 away to a certain place; then the heat is dissipated via the second fins 122 to the surrounding air away from the air surrounding the component to be cooled. That is, the second heat transferring body 120 with the second fins 122 can dissipate heat to a place further away from the component to be cooled than the first heat transferring body 110 with the first fins 112 itself. Therefore, the first and second heat transferring bodies 110, 120 can dissipate the heat to the air in different areas; preferably the areas are at different distances from the component to be cooled. This serves to reduce the high temperature of the air surrounding the component to be cooled in the conventional heat dissipation device, thus increasing the heat exchanging efficiency between the ambient air and the heat dissipation device 100 thus improving the heat dissipation capabilities.

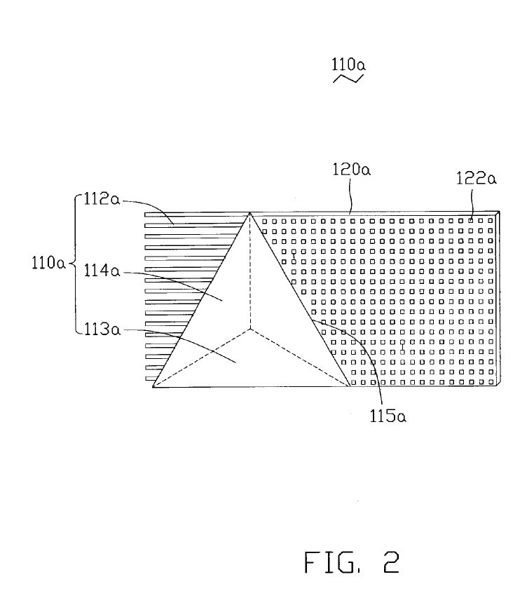

As shown in FIG. 1, the first heat transferring body 110 is an elongated cube. Of course, the first heat transferring body may be in different shapes, for example, the first heat transferring body may be another polygonal-sided prism, such as a triangular-sided prism, an octahedral prism and so on. Some more embodiments are shown in FIGS. 2-5, which will be described in the following text in details.

FIG. 2 illustrates a heat dissipation device 100a in accordance with a second embodiment. The heat dissipation device 100a comprises a first heat transferring body 110a with a triangular polyhedron or pyramid-like outer shape, and a second heat transferring body 120a extending from an edge 115a of the first heat transferring body 110a. A plurality of second pin fins 122a are attached to sides of the second heat transferring body 120a. The first heat transferring body 110a has a base 113a for contacting with a component to be cooled, and three slanting side surfaces 114a for guiding air flow downwards towards the base 113a. A plurality of first pin fins 112a extend outwardly from the slanting side surfaces 114a (only a few pin fins 112a shown in FIG. 2) of the first heat transferring body 110a along a horizontal direction. The first pin fins 112a are located in an area near the component to be cooled, while the second pin fins 122a are in an area further away from the component to be cooled than the first pin fins 112a. In one embodiment, the first heat transferring body 110a may be other kinds of pyramids or in a form of a truncated pyramid. Furthermore, a heat-transferring component with a slanting surface for guiding air flowing toward a certain direction may serve as a first heat transferring body in a similar manner described above.

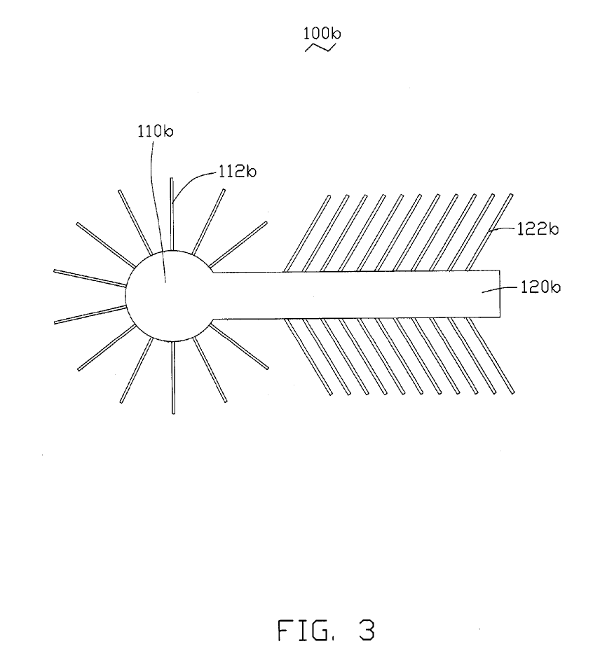

FIG. 3 illustrates a heat dissipation device 100b in accordance with a third embodiment. The heat dissipation device 100b comprises a first heat transferring body 110b with a cylindrical outer figuration, and a second heat transferring body 120b outwardly extending from the first heat transferring body 110b. A plurality of first fins 112b radially and outwardly extend from the circumference of the first heat transferring body 110b, and is in an area surrounding the first heat transferring body 110b, of which a bottom surface is attached to a top surface of a component to be cooled. A plurality of second fins 122b extend at a slant from opposite sides of the second heat transferring body 120b; thus, the second heat transferring body 120b together with the second fins 122b has a fishbone-like cross sectional configuration. As shown in FIG. 3, the second fins 122b are in an area apart from the first fins 112b, which are used to mitigate the high temperature around the first heat transferring body 110b. Furthermore, the first heat transferring body 110b may have a conical outer figuration.

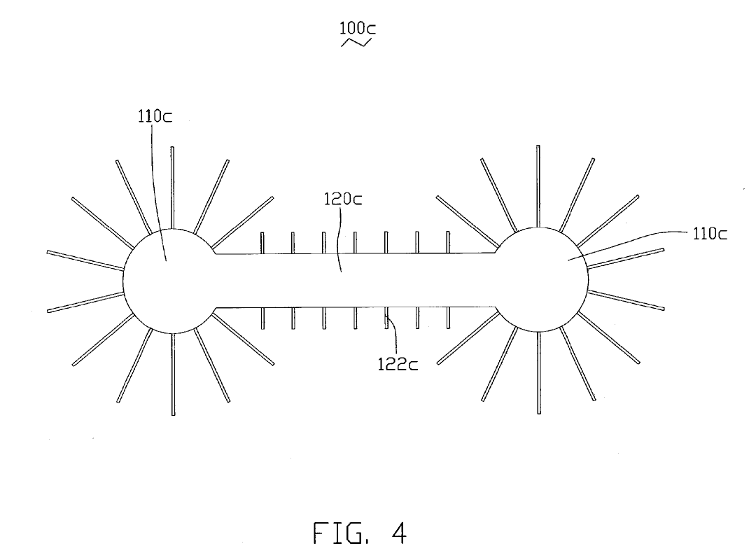

FIG. 4 illustrates a heat dissipation device 100c in accordance with a fourth embodiment. The heat dissipation device 100c is similar to the heat dissipation device 100b as described in the third preferred embodiment. The heat dissipation device 100c is dumbbell shaped, comprising a pair of spaced first heat transferring bodies 110c and a second heat transferring body 120c interconnecting the two first heat transferring bodies 110c. The first heat transferring bodies 110c are similar to the first heat transferring body 110b of the third preferred embodiment. One first heat transferring body 110c is for contacting a component to be cooled and absorbing the heat therefrom; the other one is used for dissipating part of the absorbed heat. The second heat transferring body 120c serves as a bridge, transferring heat from one first heat transferring body 110c to the other. There are some smaller fins 122c attached to sides of the second heat transferring body 120c to increase heat-exchanging area of the second heat transferring body 120c.

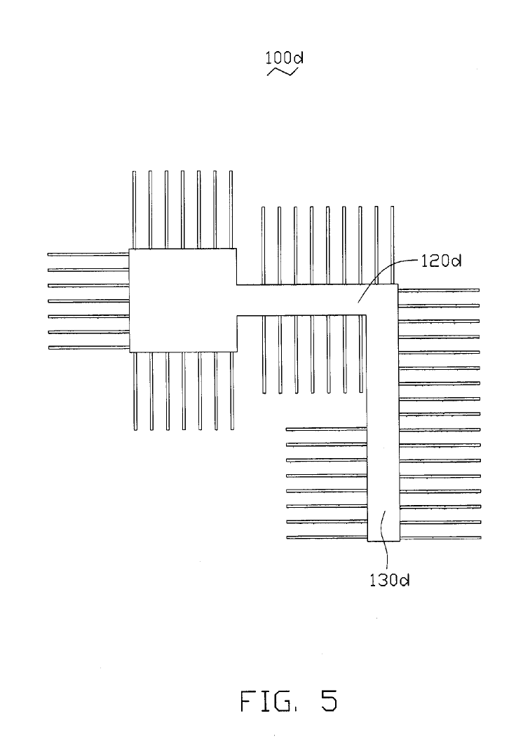

FIG. 5 illustrates a heat dissipation device 100d in accordance with a fifth embodiment. The heat dissipation device 100d is similar to the heat dissipation device 100 as described in the first preferred embodiment. The main difference is that the heat dissipation device 100d further comprises a third heat transferring body 130d bent perpendicularly from an end of the second heat transferring body 120d. The presence of the third heat transferring body 130d is used to avoid interfering with other components scattered around the component to be cooled when the second heat transferring body 120d makes its way to a proper place having larger space or lower temperature, inside or outside of a computer enclosure in which the heat dissipation device 100d is used.

In the preferred embodiments as described above, each of the heat dissipation devices has one second heat transferring body, which transfers part of the heat accumulated at the first heat transferring body to a place away from the heat source. Therefore, the temperature of the air surrounding the heat source is efficiently reduced, and the heat exchanging efficiency between the heat source and the heat dissipation device is improved. Thus, the heat dissipating capability of the heat dissipation device is improved.

For further improving the heat dissipating capability, the heat dissipation device may further comprise a heat-conducting member in combination with the first and second heat transferring bodies as described above. The heat-conducting member has a higher thermal conductivity than the first and second heat transferring bodies. In this situation, the first and second heat transferring bodies may be made of metal such as aluminum, copper, while the heat-conducting member may be selected from the group consisting of copper, heat pipes, water cooling blocks with inlets and outlets allowing water to circulate therethrough and so on. The relationships between the heat-conducting member and the first and second heat transferring bodies will be illustrated in following text in more detail.

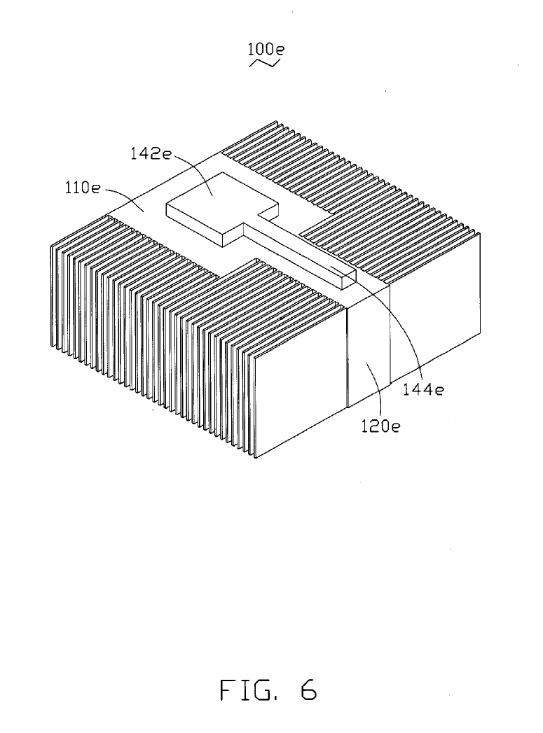

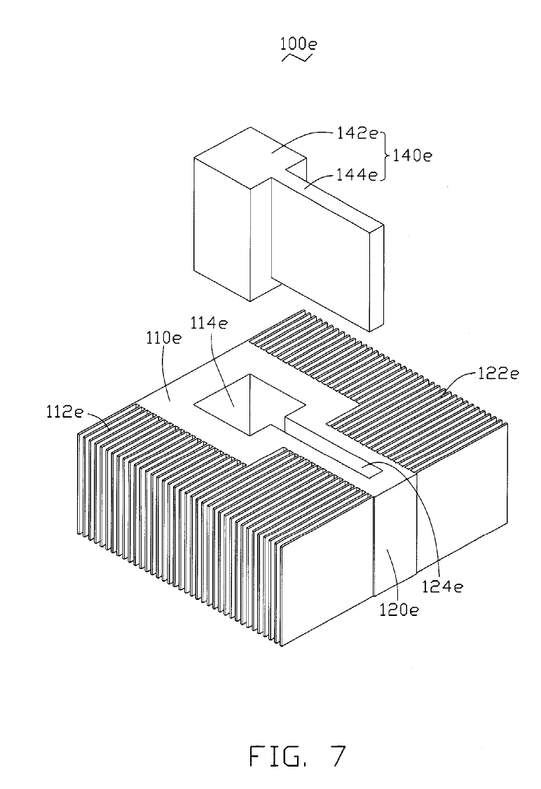

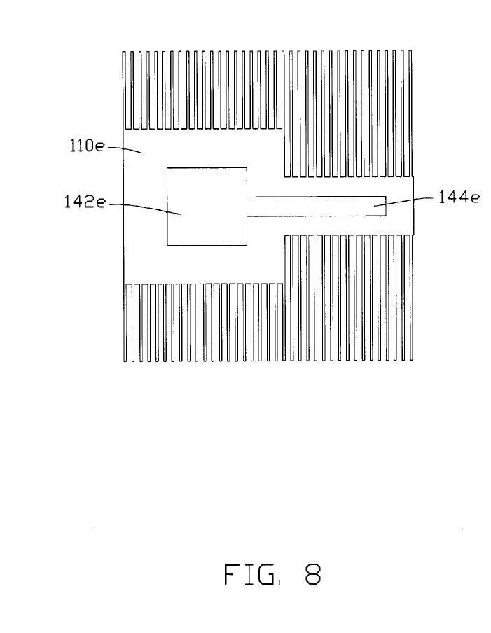

FIGS. 6-8 show a heat dissipation device 100e in accordance with a sixth embodiment. The heat dissipation device 100e is similar to the heat dissipation device 100 as described in the first preferred embodiment. The main difference is that an opening 114e is defined through the first heat transferring body 110e; a slot 124e is defined through the second heat transferring body 120e and in communication with the opening 114e. Therefore, the opening 114e and the slot 124e together form a receiving space, and a heat-conducting member 140e is installed into the receiving space. The heat-conducting member 140e has a quite similar outer figuration to that of the first and second heat transferring bodies 110e, 120e; it can be divided into a first portion 142e received in the opening 114e and a second portion 144e received in the slot 124e. The first portion 142e has a bottom surface positioned in same plane as the bottom surfaces of the first and second heat transferring bodies 110e, 120e for directly contacting with a component to be cooled. In use, the first portion 142e absorbs heat from the component to be cooled and conducts the heat to the first and second fins 112e, 122e via the first and second heat transferring bodies 110e, 120e; then the heat is dissipated to the air in different areas. The heat-conducting member 140e has a higher thermal conductivity than the first and second heat transferring bodies 110e, 120e, thus enabling it to quickly transfer heat originating at the component to be another place for dissipation.

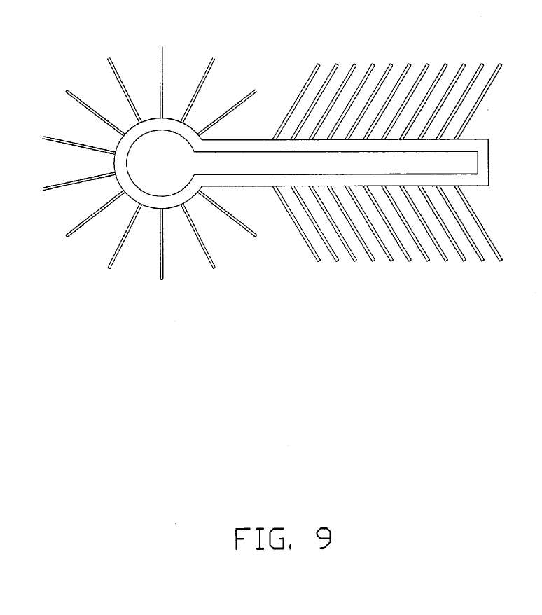

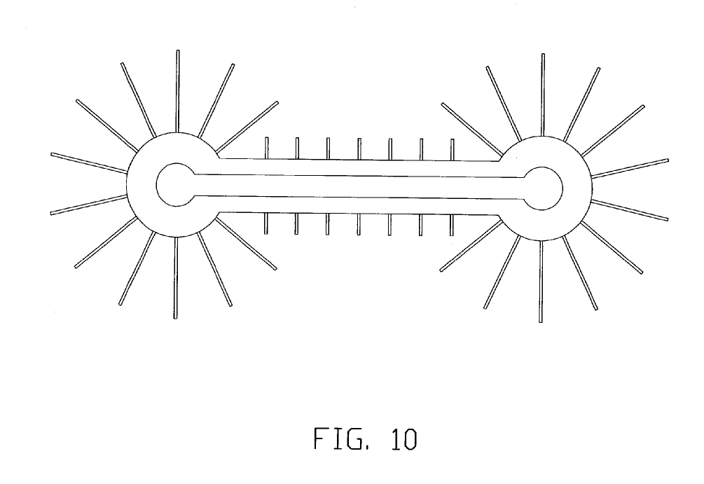

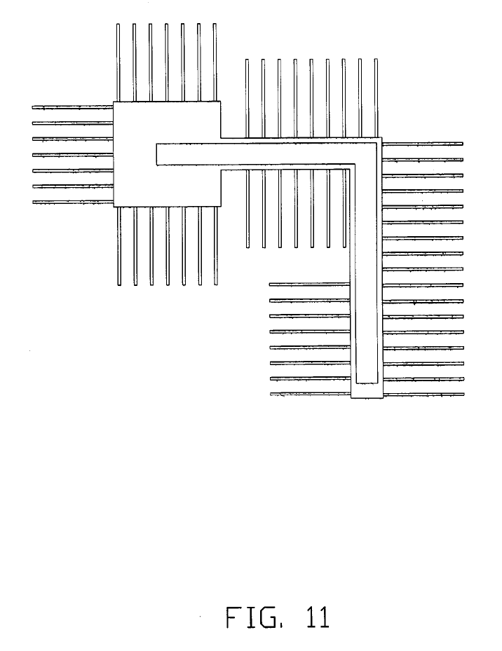

FIG. 9 illustrates a heat dissipation device in accordance with another preferred embodiment of the present invention, which has structures similar to the corresponding third embodiment as described above. FIG. 10 illustrates a heat dissipation device in accordance with another preferred embodiment of the present invention, which has structures similar to the corresponding fourth embodiment as described above. FIG. 11 illustrates a heat dissipation device in accordance with another preferred embodiment of the present invention, which has structures similar to the corresponding fifth embodiment as described above. Each heat dissipation device 100b (100c, 100d) further comprises a heat-conducting member with a similar outer figuration to the corresponding heat dissipation device 100b (100c, 100d), and the heat-conducting member is combined with the corresponding heat dissipation device 100b (100c, 100d) in a similar manner as is described in the sixth embodiment.

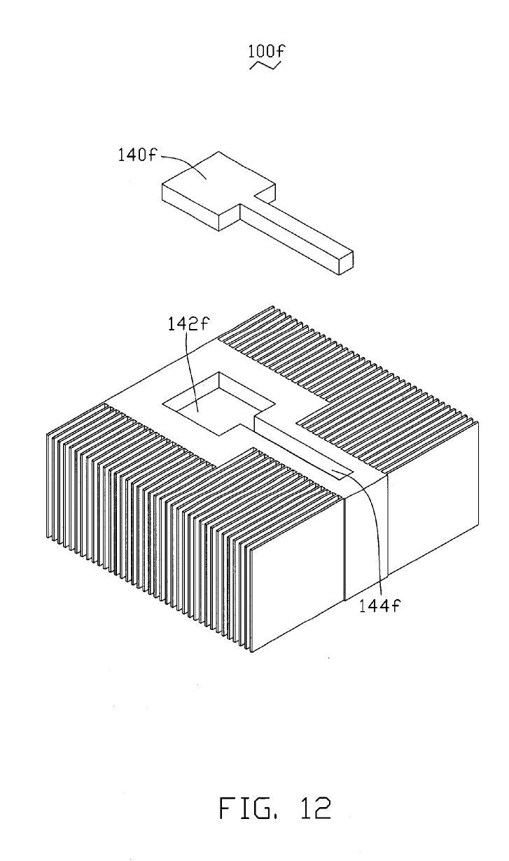

As shown in FIGS. 6-11, the receiving spaces are defined through corresponding heat dissipation devices for receiving the heat-conducting members therein. However, there may be some variations in the combination manner between the heat-conducting member and the first and second heat transferring bodies. In one embodiment, a heat dissipation device 100f shown in FIG. 12 comprises a receiving space defined in a bottom thereof for receiving a flattened heat-conducting member 140f. The receiving space is formed from a depression 142f and a groove 144f extending from the depression 142f. In another embodiment, the flattened heat-conducting member is directly attached to a bottom surface of the heat dissipation device without the presence of the receiving space.

As described above, the heat-conducting member has a higher thermal conductivity than the first and second heat transferring bodies. The heat-conducting member also can be another type of heat heat-conducting component, which has at least one difference from the first and second heat transferring bodies as described above. For example, the first and second heat transferring bodies may be made of foam metal such as aluminum foam or copper foam, while the heat-conducting member may be selected from a metal such as aluminum or copper, or a heat pipe may be used and so on. The first and second bodies have a large number of pores therein; thus, they should have a larger heat exchanging area than the heat-conducting member.

It is can be understood that the first fins may perpendicularly, or radially, or slantingly extend outwardly from the first heat transferring bodies. The second fins may also perpendicularly, or radially, or slantingly extend outwardly from the second heat transferring bodies. Each of the heat dissipation devices described above may further comprise a third heat transferring body extending from an end of the corresponding second heat transferring body, just like that of the fifth preferred embodiment.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device, comprising:
a first heat transferring body having a surface in thermal contacting with a component to be cooled and a plurality of first fins mounted thereon; and
a second heat transferring body extending from the first heat transferring body with a plurality of second fins mounted thereon, wherein the second heat transferring body with the second fins can dissipate heat originating at the component to be cooled to a place further away from the component to be cooled than the first heat transferring body with the first fins, the first and second heat transferring bodies being integrally formed by a same material with the second heat transferring body having a cross sectional configuration different from that of the first heat transferring body.

2. The heat dissipation device as claimed in claim 1, wherein the first heat transferring body has an outer shape selected from the group consisting of polygonal prisms, polygon-bottomed pyramids, truncated pyramids, cylinder and cone.

3. The heat dissipation as claimed in claim 2, wherein the second fins extend at a slant from opposite sides of the second heat transferring body, and the second heat transferring body together with the second fins has a fishbone cross sectional configuration.

4. The heat dissipation device as claimed in claim 1, further comprising another first heat transferring body separated from the first heat transferring body, the second heat transferring body interconnecting the two first heat transferring bodies.

5. The heat dissipation device as claimed in claim 4, wherein the heat dissipation has a dumbbell cross sectional configuration.

6. The heat dissipation device as claimed in claim 1, further comprising a third heat transferring body bent from an end of the second heat transferring body, the second and third heat transferring bodies each having a cross section smaller than that of the first heat transferring body.

7. The heat dissipation device as claimed in claim 6, wherein the third heat transferring body comprises a plurality of fins extending from sides thereof.

8. The heat dissipation device as claimed in claim 1, further comprising a receiving space defined therein, and a heat conducting member installed in the receiving space.

9. The heat dissipation device as claimed in claim 8, wherein the heat-conducting member has a higher thermal conductivity than the first and second heat transferring bodies.

10. The heat dissipation device as claimed in claim 9, wherein the heat-conducting member may be selected from the group consisting of metals, heat pipes, and liquid blocks with inlets and outlets to allow liquid to circulate therethrough.

11. The heat dissipation device as claimed in claim 8, wherein the first and second heat transferring bodies are made of foam metal, which has more heat exchanging area than the heat transferring member selected from the group of metal, heat pipe, and water block.

12. The heat dissipation device as claimed in claim 8, wherein the receiving space comprises an opening defined through the first heat transferring body, the heat-conducting member comprises a first portion installed into the opening.

13. The heat dissipation device as claimed in claim 12, wherein the receiving space further comprises a slot defined through the second heat transferring body and in communication with the opening, the heat-conducting member further comprises a second portion extending from the first portion into the slot.

14. The heat dissipation device as claimed in claim 8, wherein the receiving space comprises a depression defined in a bottom surface of the first heat transferring body, the heat-conducting member comprises a first portion installed into the depression.

15. The heat dissipation device as claimed in claim 14, wherein the receiving space further comprises a groove defined in a bottom surface of the second heat transferring body and in communication with the depression, the heat-conducting member further comprises a second portion installed into the groove.

16. The heat dissipation device as claimed in claim 1, further comprising a heat-conducting member attached to a bottom surface thereof.

17. The heat dissipation device as claimed in claim 1, wherein the second heat transferring body lengthwise extends from the first heat transferring body.

18. A heat dissipation device comprising:
a body having a first portion and a second portion with a smaller cross section than the first portion integrally extending from the first portion, wherein the first portion has a face adapted for contacting with a heat-generating electronic component; and
a plurality of fins attached to at least one of the first and second portions of the body.

19. The heat dissipation device as claimed in claim 18, wherein the body defines a cavity therein, and a heat-conducting member which has a thermally conductivity higher than that of the body is embedded in the cavity, the heat-conducting member having a first portion in the first portion of the body and a second portion in the second portion of the body, the second portion of the heat-conducting member having a cross section smaller than that of the first portion of the heat-conducting member, and wherein the first portion of the heat-conducting member has a face adapted for contacting with the heat-generating electronic component.

20. The heat dissipation device as claimed in claim 19, wherein the first portion of the body has a round cross section while the second portion of the body has a rectangular cross section.
